(19) United States
(12) Patent Application Publication
(10) Pub. No.: US 2026/0074693 A1
(43) Pub. Date: Mar. 12, 2026

(54) HIGH BANDGAP SWITCHED SHUNT CAPACITOR ARCHITECTURE

(71) Applicant: Applied Materials, Inc., Santa Clara, CA (US)

(72) Inventors: CHRISTOPHER OWEN, Chandler, AZ (US); DAVID COUMOU, Webster, NY (US)

(21) Appl. No.: 19/195,644

(22) Filed: Apr. 30, 2025

Related U.S. Application Data
(60) Provisional application No. 63/692,638, filed on Sep. 9, 2024.

(51) Int. Cl. H03K 17/687

(52) U.S. Cl. CPC H03K 17/6871

(57) ABSTRACT

Embodiments described herein relate to an apparatus that includes a first transistor with a first terminal, a first gate, and a second terminal. In an embodiment, the apparatus further includes a second transistor with a third terminal, a second gate, and a fourth terminal. In an embodiment, the second terminal of the first transistor is electrically coupled to the fourth terminal of the second transistor by an electrically conductive path, and the third terminal is grounded. In an embodiment, a power supply is electrically coupled to the first terminal of the first transistor. In an embodiment, the apparatus further comprises a capacitor that is electrically coupled to the electrically conductive path. In an embodiment, a power source is electrically coupled to the electrically conductive path.

### CROSS-REFERENCE TO RELATED APPLICATIONS

This application claims the benefit of U.S. Provisional Application No. 63/692,638, filed on Sep. 9, 2024, the entire contents of which are hereby incorporated by reference herein.

### BACKGROUND

### 1) Field

Embodiments of the present disclosure pertain to the field of plasma systems that include a multi-stage solid state impedance match.

### 2) Description of Related Art

In plasma processing tools (e.g., plasma etching chambers, plasma deposition chambers, plasma treatment chambers, etc.), precise control of the source power delivered to the chamber is needed to control the efficiency for the plasma system and prevent damage from reflected power back to the power source. Impedance matching is one parameter that is useful for controlling the power delivered to the chamber. For example, an impedance match is used to match the impedance of the power delivery system to the load impedance within the chamber.

Existing impedance match solutions include electro-mechanical devices and solid-state devices. Electro-mechanical devices are useful for high power applications, but they do not allow for rapid adjustments due to the use of a mechanical motor that is orders of magnitude slower than the ion transition rates across a plasma sheath. Solid state devices provide improved speed but are limited in voltage and/or current handling capability. Solid state devices also suffer from poor resolution.

### SUMMARY

Embodiments described herein relate to an apparatus that includes a first transistor with a first terminal, a first gate, and a second terminal. In an embodiment, the apparatus further includes a second transistor with a third terminal, a second gate, and a fourth terminal. In an embodiment, the second terminal of the first transistor is electrically coupled to the fourth terminal of the second transistor by an electrically conductive path, and the third terminal is grounded. In an embodiment, a power supply is electrically coupled to the first terminal of the first transistor. In an embodiment, the apparatus further comprises a capacitor that is electrically coupled to the electrically conductive path. In an embodiment, a power source is electrically coupled to the electrically conductive path.

Embodiments described herein relate to an apparatus that includes a capacitor with a first terminal and a second terminal. In an embodiment, a pullup transistor is electrically coupled to the first terminal, and a pulldown transistor is electrically coupled to the first terminal. In an embodiment, a half-bridge driver is configured to control the pullup transistor and the pulldown transistor.

Embodiments described herein relate to an apparatus that includes a board and an electrically conductive trace on the board. In an embodiment, a plurality of switched shunt capacitors are electrically coupled to the board, and each of the plurality of switched shunt capacitors are configured to be charged and discharged by a corresponding circuit that includes a transistor with a semiconductor material with a bandgap that is 1.5 eV or higher.

### BRIEF DESCRIPTION OF THE DRAWINGS

FIG. 1A is a schematic illustration of a multi-stage match that includes banks of switched shunt capacitors that are controlled by high bandgap transistor devices, in accordance with an embodiment.

FIG. 1B is a schematic illustration of a multi-stage match that includes banks of switched shunt capacitors that are controlled by high bandgap transistor devices that include a sensor at a power output of the match, in accordance with an embodiment.

FIG. 1C is a schematic illustration of a plasma processing tool that comprises a power generator, a multi-stage solid state impedance match, and a plasma chamber, in accordance with an embodiment.

FIG. 2A is a schematic illustration of a second stage of an impedance match with a pair of capacitor banks, in accordance with an embodiment.

FIG. 2B is a schematic illustration of a first stage of an impedance match with a set of three capacitor banks, in accordance with an embodiment.

FIG. 2C is a schematic diagram of a capacitor bank that may be used in any of the stages of an impedance match, in accordance with various embodiments.

FIG. 3A is a circuit diagram of an individual switched shunt capacitor that is controlled by a high band-gap transistor, in accordance with an embodiment.

FIG. 3B is a circuit diagram of an individual switched shunt capacitor that is controlled by a high band-gap transistor and a switch, in accordance with an embodiment.

FIG. 3C is a circuit diagram of an individual switched shunt capacitor that is controlled by a pair of transistors arranged in a half-bridge configuration, in accordance with an embodiment.

FIG. 4 is an illustration of a block diagram of an exemplary computer system that may be used in conjunction with a processing tool, in accordance with an embodiment.

### DETAILED DESCRIPTION

Plasma systems that include a multi-stage solid state impedance match are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, impedance matches provide the control that enables efficient power delivery to plasma processing tools (e.g., plasma etching chambers, plasma deposition chambers, plasma treatment chambers, etc.). In order to provide the high switching speed needed for many plasma processes, solid state impedance matches have become a popular option. However, the low voltage and/or current handling capability and poor resolution of existing solid-state options renders such systems not suitable for high power environments.

Accordingly, embodiments disclosed herein may include solid state impedance matches that are based on high bandgap transistor devices. For example, high bandgap transistors (also sometimes referred to as wide bandgap transistors) may have a bandgap in the range of approximately 1.5 eV to approximately 4.0 eV or higher. In a particular embodiment, silicon carbide (SiC) transistors may be used in order to switch capacitors on and off in order to modify an impedance of the power delivery network. SiC transistor devices provide low RDSon, low parasitic capacitances (Coss), and may include VA ratings suitable for use in high-power RF networks. While SiC transistors are included as one option herein, it is to be appreciated that any suitable high bandgap transistor may be used, such as a GaN transistor, other III-V group semiconductor transistors, or the like. These high bandgap transistors enable the use of a broad capacitance range with optimized switching characteristics and faster stabilization of plasma generation to achieve high performance and through a cost effective solution.

In some instances, a limitation for DC bias voltages used to vary the capacitance of a cell arrangement of diodes is the rise time of the DC power supply. The current draw for the DC power is a function of the rise time. As such, reverse biasing of diodes may need a low current in some of the embodiments disclosed herein. This allows for a DC power rise time that is approximately 10 μs or less or approximately 1.0 μs or less. Such fast switching speeds may lead to significantly expanded process regimes for the plasma processing tool. The fast switching may also provide new tool capabilities for the control of plasma loads in the semiconductor industry. Faster switching times also speed up process times and reduces the total energy consumed by the process.

In an embodiment, the solid-state match may comprise a multi-stage matching network. In some embodiments, the multi-stage matching network may include a first matching network and a second matching network. In some instances, cascaded stages are implemented to adjust impedance transformation and coupling between stages for optimal minimization of losses while maximizing power efficiency by tailoring parasitic coupling and resistive losses from solid-state devices. Though, it is to be appreciated that embodiments disclosed herein may also be practiced with a single stage. In an embodiment, the solid-state impedance tuning system may be integrated with an RF power amplifier for unified power compensation and impedance control. This allows for optimal load power control for plasma stability through a wide dynamic impedance variation during plasma ignition and multi-rate pulsing. In some embodiments, the match may also provide harmonic attenuation. This allows for a reduction in the complexity of an RF generator harmonic filter. Additionally, high Q components can be used. This allows for greater reduction in RF losses, which is particularly beneficial for low plasma load impedances.

In an embodiment, switched shunt capacitors described herein may be biased by a high voltage power source. The high voltage bias is used to prevent conduction of the transistor body diode when the RF waveform goes negative. Also, the high voltage bias is used to bias the drain voltage to a point where the Coss is low and below the maximum voltage rating of the transistor for long term reliability. With high voltage switching, the shunt switched capacitor transistor provides a faster rise time. As such, a faster impedance switching is provided, and power losses are minimized within the impedance match. High voltage switching may also reduce transients on the RF power waveform.

One issue with the use of a high voltage power source is that the continuous power provided by the high voltage bias can be lost through leakage. An always on high voltage bias can also delay the speed and RF performance of the shunt switched capacitor. Accordingly, embodiments disclosed herein may include a switch (e.g., a single pole, single throw (SPST) switch) that is used to disconnect the high voltage bias when the capacitor is switched off. As such, efficiency and RF performance may be improved. Embodiments disclosed herein may also allow for a reduction of the out of band transient voltages and energy on the main RF power path as a result of delayed switching off the shunt capacitance. This transient energy occurs during reverse conduction in the body diode of the transistor. Out of band energy is mismatched due to the high Q load and interferes with the RF generator metrology and power regulation.

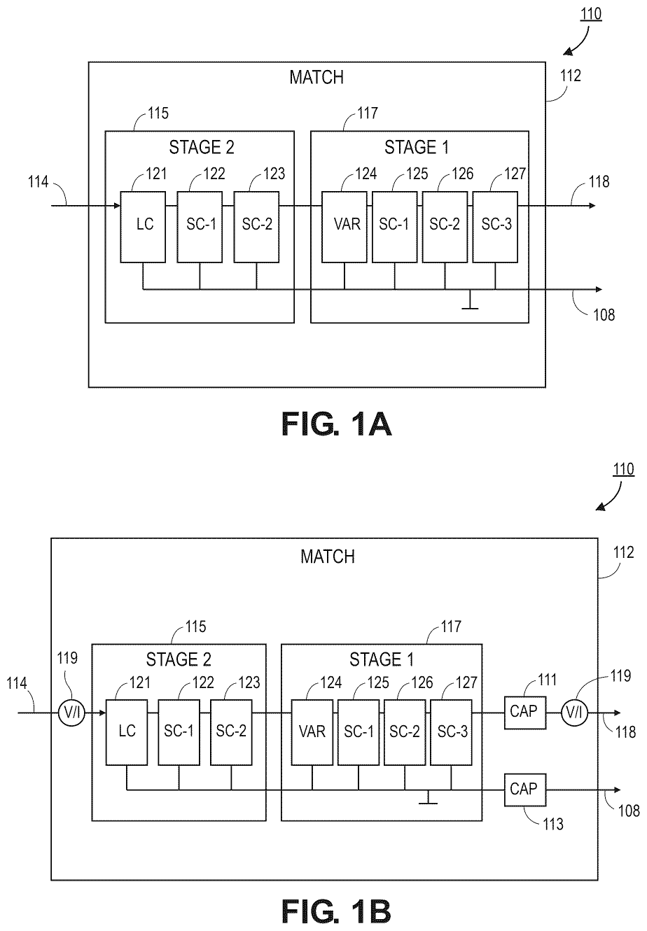

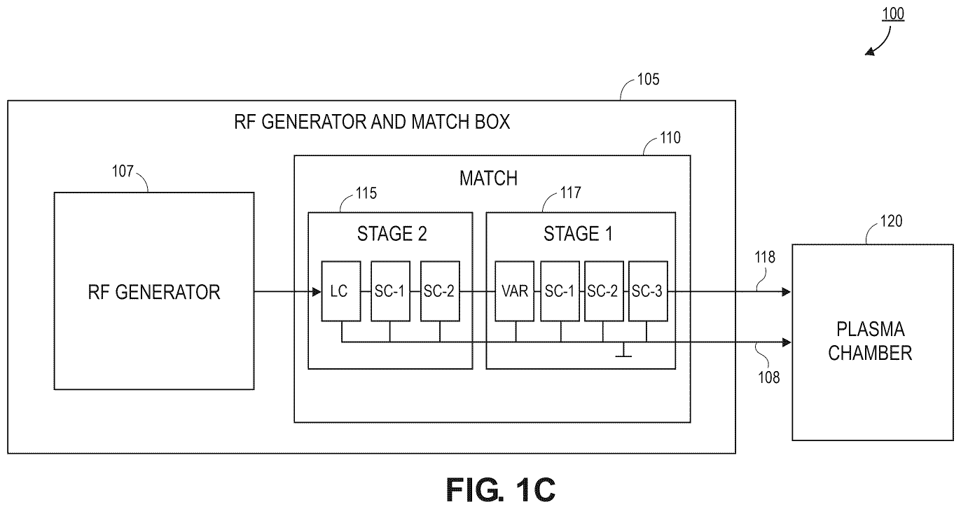

Referring now to FIG. 1A, a schematic illustration of an impedance match 110 is shown, in accordance with an embodiment. In an embodiment, the impedance match 110 may be an RF impedance match. For example, an RF generator (not shown) may provide RF power to an input 114 of the impedance match 110. Similarly, impedance matched power may exit the impedance match 110 at output 118. A ground line 108 may also be coupled to the impedance match 110.

In an embodiment, the impedance match 110 may comprise a board 112 for mounting one or more impedance matching stages. For example, a second stage 115 may be provided at the input 114, and a first stage 117 may be provided at the output 118. In the illustrated embodiment, the first stage 117 and the second stage 115 are provided on separate boards. Though, the first stage 117 and the second stage 115 may also be on the same board in some embodiments. Additionally, while two stages 117 and 115 are shown in FIG. 1A, it is to be appreciated that three or more stages may also be used in some embodiments. That is, the number of stages is scalable to fit the needs of a desired application.

In an embodiment, the second stage 115 may include an LC module 121 (e.g., a circuit element comprising one or more capacitors and one or more inductors). The LC module 121 may feed into a first switched shunt capacitor bank 122 and a second switched shunt capacitor bank 123. While shown in FIG. 1A, other embodiments may omit the LC module 121. In an embodiment, the switched shunt capacitor banks 122 and 123 may each comprise a plurality of switched shunt capacitors that are each turned on/off through the use of high bandgap transistors, such as a SiC transistor or the like. A more detailed explanation of the switched shunt capacitors will be provided in greater detail herein.

While a first switched shunt capacitor bank 122 and a second switched shunt capacitor bank 123 are shown in FIG. 1A, it is to be appreciated that any number of switched shunt capacitor banks may be used in the second stage 115. Each of the switched shunt capacitor banks 122 or 123 may comprise any number of high bandgap capacitors in order to provide a desired level of capacitance along the RF path between the input 114 and the output 118. The individual capacitors within a single capacitor bank may include different capacitance values or two or more of the individual capacitors within a single capacitor bank may have the same capacitance value.

In an embodiment, the second stage 115 may be used to convert an impedance of the power delivery network to match an impedance of an RF generator (not shown). For example, the impedance of the RF generator may be approximately 50 Ohms. In an embodiment, the first stage 117 may be used to match the impedance of the load coupled to the power delivery network (e.g., a plasma within a chamber coupled to the impedance match 110).

In an embodiment, the first stage 117 may be electrically coupled to the second stage 115. The first stage 117 may comprise a varactor 124 and a plurality of additional switched shunt capacitor banks 125, 126, and 127. The varactor 124 may allow for an analog (i.e., substantially continuous) control of the impedance before reaching the additional switched shunt capacitor banks 125, 126, and 127. While shown as being within the first stage 117, other embodiments may include inserting the varactor 124 in the second stage 115 (e.g., before the switch shunt capacitor banks 122 and 123) or as a discrete system between the first stage 117 and the second stage 115. In an embodiment, the varactor 124 may also be implemented as a solid state component. In such an embodiment, the varactor 124 may comprise high bandgap transistors, such as SiC transistors.

In an embodiment, the first stage 117 may be used to control an impedance from between approximately 0.2 Ohms to approximately 10 Ohms in order to match a load impedance within a plasma chamber that is electrically coupled to the output 118. Further, the first stage 117 may be used to transfer the whole range of complex load impedances to a purely resistive impedance for the desired range (e.g., approximately 0.2 Ohms to approximately 10 Ohms).

While three different switched shunt capacitor banks 125, 126, and 127 are shown in FIG. 1A, it is to be appreciated that any number of switched shunt capacitor banks may be used in the first stage 117. Each of the switched shunt capacitor banks 125, 126, and 127 may comprise any number of high bandgap capacitors in order to provide a desired level of capacitance along the RF path between the input 114 and the output 118. The individual capacitors within a single capacitor bank may include different capacitance values or two or more of the individual capacitors within a single capacitor bank may have the same capacitance value.

Referring now to FIG. 1B, a plan view illustration of an impedance match 110 is shown, in accordance with an additional embodiment. In an embodiment, the impedance match 110 in FIG. 1B may be similar to the impedance match 110 in FIG. 1A, with the addition of capacitors 111 and 113. The capacitors 111 and 113 may by extremely high Q components in order to improve performance of the match 110 in some embodiments. For example, the capacitors 111 and 113 may be vacuum capacitors. In some embodiments, one or both of capacitors 111 or 113 may be optional. Additionally, an RF sensor 119 (e.g., a voltage/current (V/I) sensor) may be provided on the impedance match 110. Particularly, a pair of RF sensors 119 are provided in FIG. 1B. A first RF sensor 119 may be provided before the second stage 115 at the input 114, and a second RF sensor 119 may be provided after the first stage 117 at the output 118. In an embodiment, the RF sensors 119 may be used in order to monitor the power delivered to the plasma chamber through the impedance match 110. This can be used for control purposes and/or for an indication of when a safe operating area (SOA) is exceeded for the impedance match 110 and/or the plasma processing tool in general.

Referring now to FIG. 1C, a schematic diagram of a plasma processing system 100 is shown, in accordance with an embodiment. In an embodiment, the plasma processing system 100 may comprise an RF generator and match box 105. The box 105 may be a housing and/or enclosure that integrates an RF generator 107 and the match 110 into a single system. The RF generator 107 may generate RF power that is delivered to a plasma chamber 120 through the match 110. In an embodiment, the match 110 may be similar to the match 110 described with respect to FIG. 1A or 1B. For example, the match 110 may comprise a plurality of stages (e.g., a first stage 117 and a second stage 115). Each of the stages 117 and 115 may comprise a plurality of switched shunt capacitor banks.

In an embodiment, the plasma chamber 120 may be chamber capable of supporting a plasma. For example, the plasma chamber 120 may be a low-pressure chamber, such as a vacuum chamber. In an embodiment, the plasma chamber 120 may include a plasma deposition chamber, a plasma etching chamber, a plasma treatment chamber, or the like. The output 118 may deliver RF power to the plasma chamber 120 in order to ignite and/or sustain a plasma within the plasma chamber 120. A ground line 108 may also be coupled between the plasma chamber 120 and the match 110.

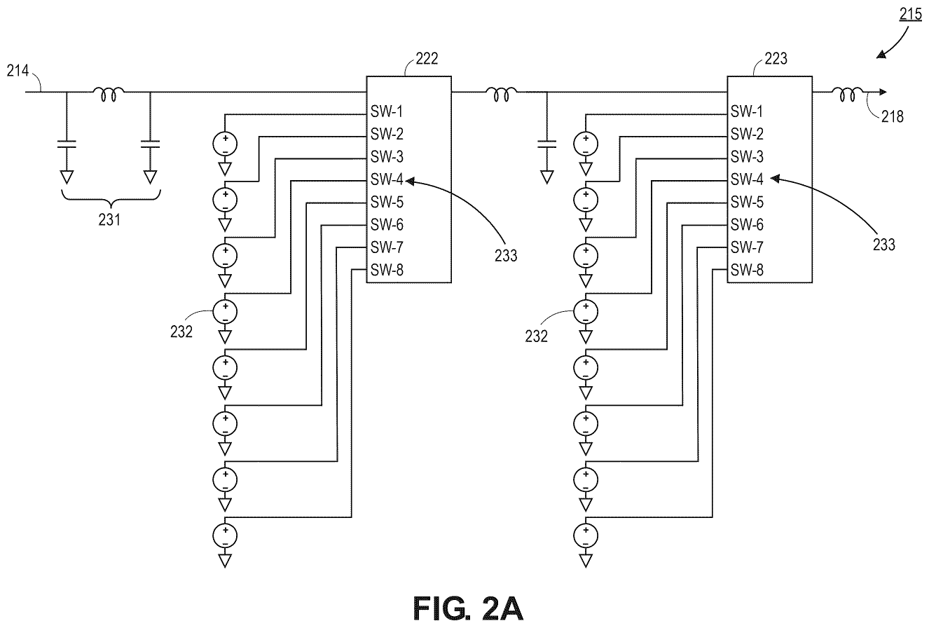

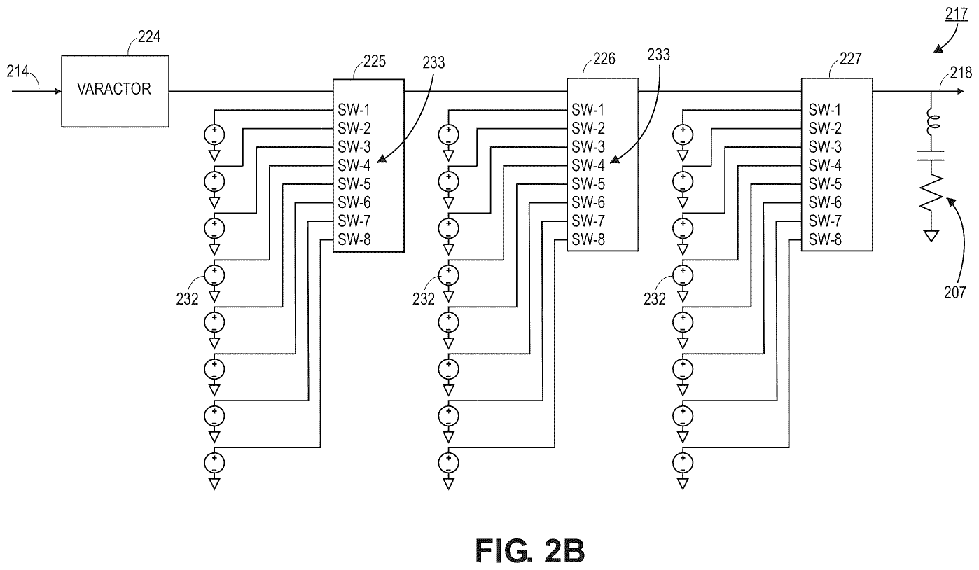

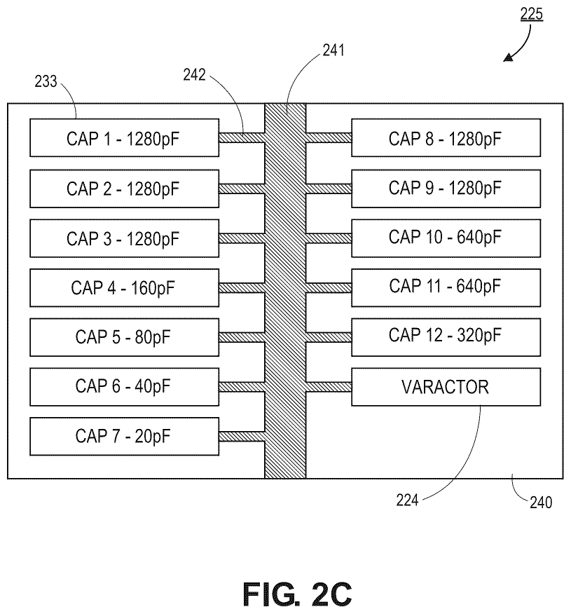

Referring now to FIGS. 2A and 2B, schematic illustrations of different stages of a multi-stage match are shown, in accordance with an embodiment. Referring now to FIG. 2A, a second stage 215 is shown, in accordance with an embodiment. As shown, an input 214 to the second stage 215 may enter an LC module 231. In an embodiment, the LC module 231 may be a circuit element comprising one or more capacitors and one or more inductors. Though, in other embodiments, the LC module 231 may be omitted. In an embodiment, the second stage 215 may continue along the main RF path to a first switched shunt capacitor bank 222 and a second switched shunt capacitor bank 223 before reaching an output 218. In an embodiment, the capacitor banks 222 and 223 each include a plurality of individual switched shunt capacitors 233. The switched shunt capacitors 233 may each be coupled to a power source 232, such as a DC power source. A more detailed description of the circuitry for the switched shunt capacitors 233 and how they are turned on/off is provided in greater detail herein.

In the illustrated embodiment, the first capacitor bank 222 and the second capacitor bank 223 have the same number of switched shunt capacitors 233. Though, in other embodiments, the capacitor banks 222 and 223 may have a different number of switched shunt capacitors 233. While eight switched shunt capacitors 233 are shown in each capacitor bank 222 and 223, it is to be appreciated that each capacitor bank 222 and 223 may comprise one or more switched shunt capacitors 233. In an embodiment, each of the switched shunt capacitors 233 may have substantially the same electrical characteristics (e.g., capacitance, Q-value, etc.). In such an embodiment, switching on a desired number of switched shunt capacitors 233 within a capacitor bank 222 or 223 can provide a desired total capacitance to the second stage 215 that is an integer multiple of the capacitance of each switched shunt capacitors 233. In some embodiments, a more granular change in the total capacitance may be provided by including switched shunt capacitors with multiple different capacitances. For example, a first switched shunt capacitor 233 may have a capacitance C, a second switched shunt capacitor 233 may have a capacitance C/2, a third switched shunt capacitor 233 may have a capacitance C/4, a fourth switched shunt capacitor 233 may have a capacitance C/8, or the like. Accordingly, more granular control of the total capacitance can be provided to the second stage 215 of the impedance match.

Referring now to FIG. 2B, a schematic illustration of a first stage 217 of the match is shown, in accordance with an embodiment. In an embodiment, the input 214 may lead into a varactor 224. The varactor 224 may provide a more granular control (e.g., analog or substantially continuous control) of the impedance. The following components may include a third capacitor bank 225, a fourth capacitor bank 226, and a fifth capacitor bank 227. In an embodiment, each of the additional capacitor banks 225-227 may be similar to the capacitor banks 222 and 223 described with respect to FIG. 2B. For example, each capacitor bank 225-227 may comprise one or more switched shunt capacitors 233 that are powered by power sources 232 (e.g., a DC power source 232). While three capacitor banks 225-227 are shown, it is to be appreciated that any number capacitor banks 225-227 may be included in the first stage 217. In some embodiments, a grounded inductor (e.g., a shunt inductor) (not shown) may be provided at the output 218 after the capacitor bank 227 in order to neutralize leakage through the match when all of the capacitors 233 are switched off. In some embodiments a second harmonic trap circuit 207 may also be provided between the last capacitor bank 227 and the output 218. The second harmonic trap circuit 207 may be used to mitigate second harmonic levels within the system. This may occur because each of the switching transistors that control the capacitors 233 have different Coss capacitance depending on whether the instantaneous drain voltage is at a high voltage or a low voltage. As such, a sine wave picks up some second harmonic distortion at each switched capacitor when the associated transistor is off. In the embodiment shown in FIG. 2B, the second harmonic trap circuit 207 comprises a shunt LC notch.

Referring now to FIG. 2C, a plan view schematic illustration of a capacitor bank 225 is shown, in accordance with an embodiment. In an embodiment, the capacitor bank 225 may comprise a board 240, such as a printed circuit board (PCB) or the like. In an embodiment, a trace 241 (e.g., an RF trace) extends across the board 240. A plurality of capacitors 233 may be coupled to the board 240 and electrically coupled to the trace 241 by traces 242. The capacitors 233 may be discrete components (described in greater detail herein) that are mounted to the board 240 with any suitable mounting option suitable for electrically coupling the capacitors 233 to the board 240 (e.g., soldering, sockets, solder interconnects, etc.).

In an embodiment, the plurality of capacitors 233 may comprise one or more different capacitance values. For example, the capacitors 233 may have capacitance values equal to 2ⁿx, where n starts at zero and increases by one for each capacitance level in order to provide a desired capacitance resolution for the capacitor bank. In the illustrated embodiment, x is equal to 20 pF and n starts at zero and goes up to six in order to provide seven different capacitance values that includes 20 pF, 40 pF, 80 pF, 160 pF, 320 pF, 640 pF, and 1280 pF. The number of capacitors 233 at each capacitance value may be tailored to provide desired total capacitance values for the capacitor bank. Though, it is to be appreciated that any collection of capacitors 233 with any desired capacitance values may be used in other embodiments.

In some embodiments, the capacitor bank 225 may also comprise a varactor 224. The inclusion of a varactor 224 may be used to provide even finer resolution for the overall capacitance of the capacitor bank 225 since the varactor 224 may provide a capacitance that can be changed in a substantially analog manner. In an embodiment, the varactor 224 may also comprise high bandgap transistors, such as any of those described in greater detail herein.

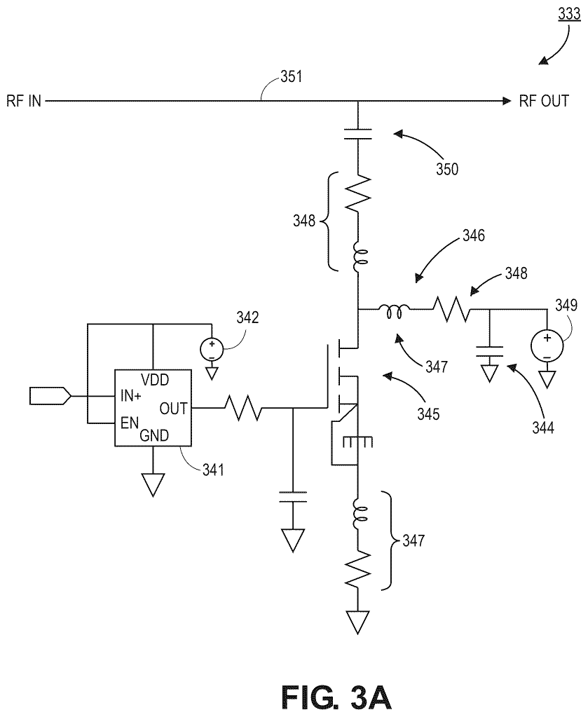

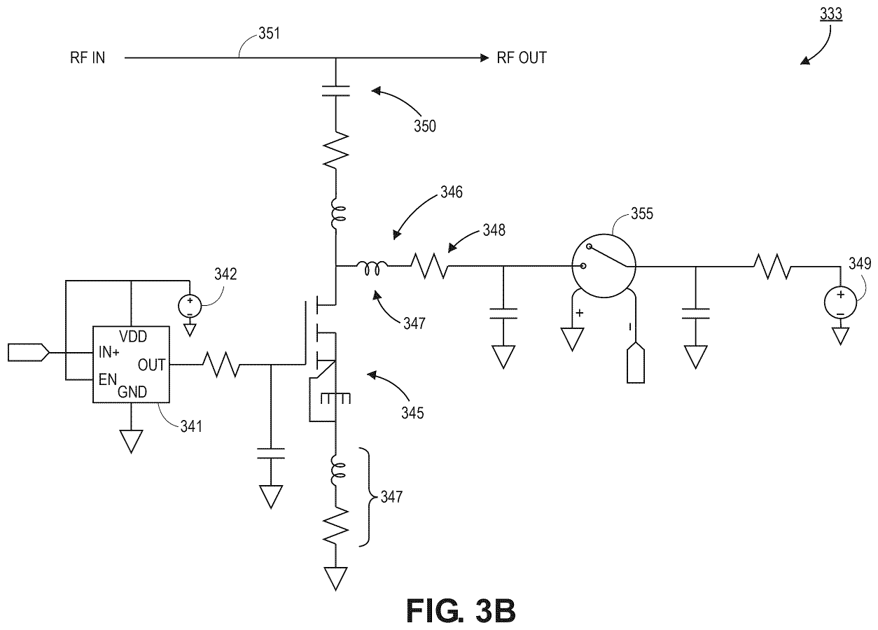

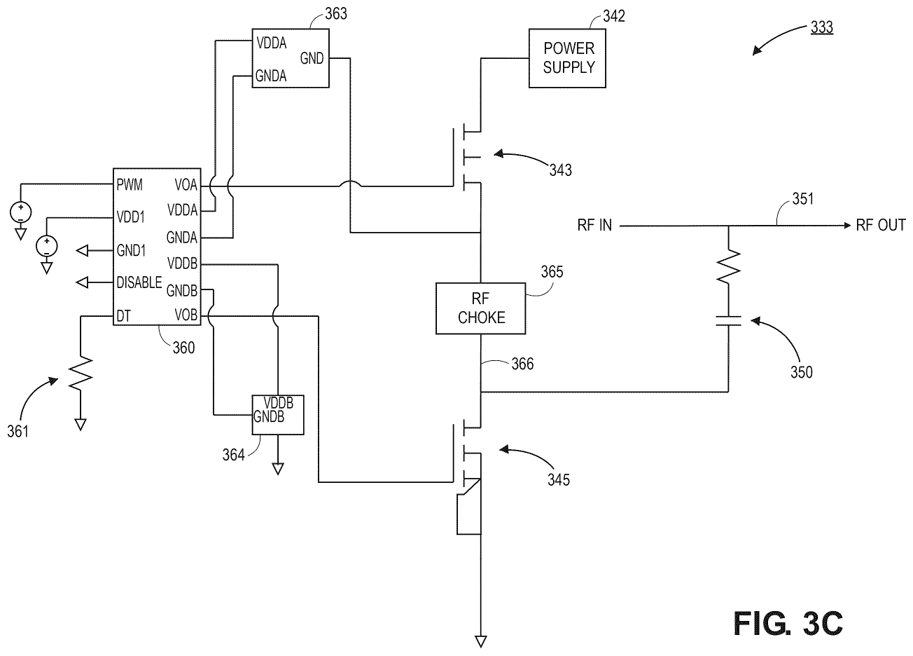

Referring now to FIG. 3A, a circuit diagram of an individual switched shunt capacitor 333 is shown, in accordance with an embodiment. In an embodiment, the switched shunt capacitor 333 may comprise a capacitor 350 that is coupled to a main RF line 351. In an embodiment, the capacitor 350 is switched from on to off through the use of a transistor 345. In an embodiment, the transistor 345 may comprise a high bandgap transistor, such as one formed with SiC, GaN, other III-V group semiconductor transistors, or the like. For example, the transistor 345 may comprise a SiC MOSFET device. The power for the transistor 345 may be provided by a power supply 342 (e.g., a DC power supply 342) that is coupled to a PWM driver 341. In an embodiment, a high voltage bias branch 346 may be provided between the transistor 345 and the capacitor 350. The high voltage bias branch 346 may comprise a high voltage power source 349, such as a high voltage DC power source. In an embodiment, some parasitic elements 347 and 348 are illustrated in the circuit for illustration purposes. A grounded capacitor 344 may also be provided between the high voltage power source 349 and the main circuit.

Referring now to FIG. 3B, a circuit diagram of an individual switched shunt capacitor 333 is shown, in accordance with an additional embodiment. The switched shunt capacitor 333 in FIG. 3B may be similar to the switched shunt capacitor 333 in FIG. 3A, with the exception of the auto-bias branch 346. For example, the auto-bias branch 346 may comprise a switch 355. The use of a switch 355 along the auto-bias branch 346 may provide improvements to the switching characteristics and/or power efficiency of the switched shunt capacitor 333. For example, an always on high voltage bias may delay the switching speed and the RF performance of the capacitor 333. Accordingly, the ability to disconnect the high voltage bias power source 349 when the capacitor 333 is switched off can improve the efficiency and RF performance. More particularly, the use of a switch 355 along the auto-bias branch 346 reduces the out of band transient voltages and energy on the main RF line 351 which may be generated when a delay is present before the shunt capacitance is switched off. This transient energy occurs during reverse conduction in the body diode of the transistor 345. Out of band energy is mismatched due to the high Q load and interferes with the RF generator metrology and power regulation.

In an embodiment, the switch 355 may be a SPST switch. Though, it is to be appreciated that any suitable type of switch 355 may be used in other embodiments. When the switch 355 is closed, the power source 349 is electrically coupled to the circuit. When the switch 355 is open, the power source 349 is disconnected from the circuit. In some embodiments, the switch 355 may be operated in unison with the transistor 345. That is, when current passes through the transistor 345, the switch 355 may also be closed in order to connect the power source 349 to the circuit. Alternatively, when the current does not pass through the transistor 345, the power source 349 is disconnected from the circuit.

Referring now to FIG. 3C, a circuit diagram of an individual switched shunt capacitor 333 is shown, in accordance with an additional embodiment. The switched shunt capacitor 333 in FIG. 3C may be driven with a half-bridge topology. For example, a pullup transistor 343 and a pulldown transistor 345 may be used to charge and discharge the capacitor 350. The pullup transistor 343 and the pulldown transistor 345 may be high bandgap transistors, such as SiC transistors, GaN transistors, other III-V group semiconductor transistors, or the like. The source of the pulldown transistor 345 may be coupled to ground, and the drain of the pullup transistor 343 may be coupled to a power supply 342. The power supply 342 may be a DC power supply.

In an embodiment, a source terminal of the pullup transistor 343 may be electrically coupled to a drain terminal of the pulldown transistor 345 by an electrical trace 366. An RF choke circuitry block 365 may be provided along the electrical trace 366. The RF choke circuitry block 365 may prevent RF propagation into the pullup transistor 343. The RF choke circuitry block 365 may include one or more RF filter circuits, inductors, and/or the like.

In an embodiment, the pullup transistor 343 and the pulldown transistor 345 may be driven by a half-bridge driver 360. The half-bridge driver 360 may have a resistor 361 coupled to the DT input to ensure that the pullup transistor 343 and the pulldown transistor 345 are not on at the same time. The resistor 361 may be chosen to provide a dead time that is approximately 0.5 μs or less.

In an embodiment, the half-bridge driver 360 may be coupled to a first power supply 363 for controlling the pullup transistor 343. That is, the first power supply 363 may be electrically coupled to the gate of the pullup transistor 343 through the half-bridge driver 360. The first power supply 363 may be held at an electrically floating voltage set by the power supply 342 (e.g., around 600V). Since the first power supply 363 is electrically floating, the first power supply 363 is capable of pulling up the voltage to block RF current from going into the pullup transistor 343. The half-bridge driver 360 may also be coupled to a second power supply 364 for controlling the pulldown transistor 345. That is, the second power supply 364 may be electrically coupled to the gate of the pulldown transistor 345 through the half-bridge driver 360. The half-bridge driver 360 allows for voltage to be applied to either the gate of the pullup transistor 343 (which allows power supply 342 to charge the capacitor 350) or to the gate of the pulldown transistor 345 (which allows the charge in the capacitor 350 to be drained to ground).

Thus, embodiments of the present disclosure include systems that include a solid-state impedance match with a multi-stage design that includes switched shunt capacitors arranged in a capacitor bank.

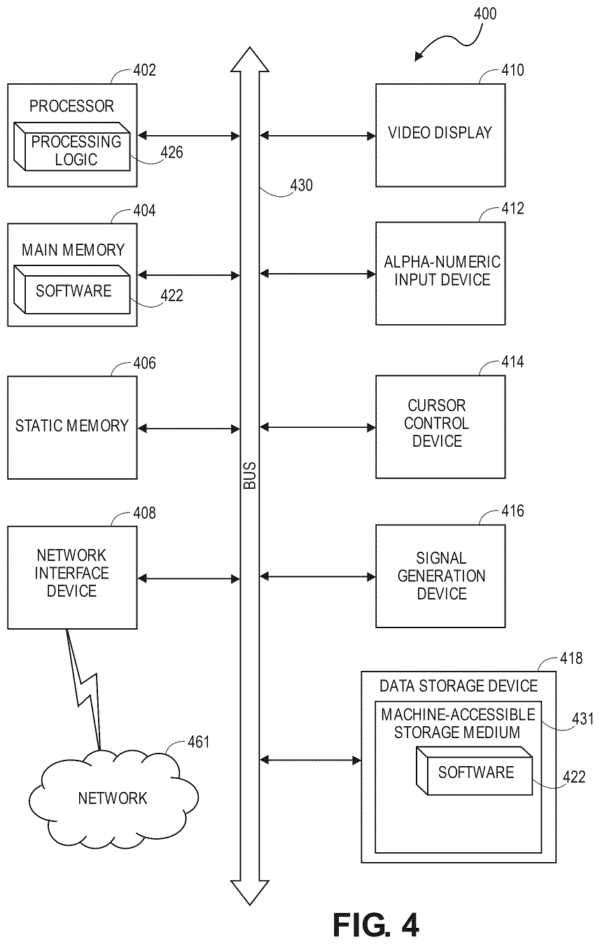

Referring now to FIG. 4, a block diagram of an exemplary computer system 400 of a processing tool is illustrated in accordance with an embodiment. In an embodiment, computer system 400 is coupled to and controls processing in the processing tool. Computer system 400 may be connected (e.g., networked) to other machines in a Local Area Network (LAN), an intranet, an extranet, or the Internet. Computer system 400 may operate in the capacity of a server or a client machine in a client-server network environment, or as a peer machine in a peer-to-peer (or distributed) network environment. Computer system 400 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 400, the term “machine” shall also be taken to include any collection of machines (e.g., computers) that individually or jointly execute a set (or multiple sets) of instructions to perform any one or more of the methodologies described herein.

Computer system 400 may include a computer program product, or software 422, having a non-transitory machine-readable medium having stored thereon instructions, which may be used to program computer system 400 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 400 includes a system processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a secondary memory 418 (e.g., a data storage device), which communicate with each other via a bus 430.

System processor 402 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 402 may also be one or more special-purpose processing devices such as an application specific integrated circuit (ASIC), a field programmable gate array (FPGA), a digital signal system processor (DSP), network system processor, or the like. System processor 402 is configured to execute the processing logic 426 for performing the operations described herein.

The computer system 400 may further include a system network interface device 408 for communicating with other devices or machines. The computer system 400 may also include a video display unit 410 (e.g., a liquid crystal display (LCD), a light emitting diode display (LED), or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium 431 (or more specifically a computer-readable storage medium) on which is stored one or more sets of instructions (e.g., software 422) embodying any one or more of the methodologies or functions described herein. The software 422 may also reside, completely or at least partially, within the main memory 404 and/or within the system processor 402 during execution thereof by the computer system 400, the main memory 404 and the system processor 402 also constituting machine-readable storage media. The software 422 may further be transmitted or received over a network 461 via the system network interface device 408. In an embodiment, the network interface device 408 may operate using RF coupling, optical coupling, acoustic coupling, or inductive coupling.

While the machine-accessible storage medium 431 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a first transistor with a first terminal, a first gate, and a second terminal;
a second transistor with a third terminal, a second gate, and a fourth terminal, wherein the second terminal of the first transistor is electrically coupled to the fourth terminal of the second transistor by an electrically conductive path, and wherein the third terminal is grounded;
a power supply electrically coupled to the first terminal of the first transistor;
a capacitor electrically coupled to the electrically conductive path; and
a power source electrically coupled to the electrically conductive path.

2. The apparatus of claim 1, wherein the first transistor and/or the second transistor comprise a silicon carbide semiconductor material.

3. The apparatus of claim 1, wherein the first transistor and/or the second transistor comprise a gallium nitride semiconductor material.

4. The apparatus of claim 1, wherein the first transistor and/or the second transistor comprise a metal-oxide-semiconductor field-effect transistor (MOSFET).

5. The apparatus of claim 1, further comprising:
an RF choke along the electrically conductive path between the first transistor and the second transistor.

6. The apparatus of claim 1, wherein the first gate and the second gate are electrically coupled to a half-bridge driver.

7. The apparatus of claim 1, wherein the capacitor is electrically coupled to an RF trace.

8. The apparatus of claim 1, wherein the power supply is a DC power supply.

9. The apparatus of claim 1, wherein the power source is electrically floating with respect to the electrically conductive path.

10. The apparatus of claim 1, wherein the first transistor and the second transistor are configured to be driven to opposite states during operation of the apparatus.

11. An apparatus, comprising:
a capacitor with a first terminal and a second terminal;
a pullup transistor electrically coupled to the first terminal;
a pulldown transistor electrically coupled to the first terminal; and
a half-bridge driver configured to control the pullup transistor and the pulldown transistor.

12. The apparatus of claim 11, wherein the pulldown transistor is electrically coupled to ground, and wherein the pullup transistor is electrically coupled to a power supply.

13. The apparatus of claim 11, further comprising:
an RF choke electrically coupled between the pullup transistor and the pulldown transistor.

14. The apparatus of claim 11, wherein the pullup transistor and/or the pulldown transistor comprise semiconductor materials with bandgaps that are 1.5 eV or higher.

15. The apparatus of claim 11, wherein the second terminal of the capacitor is electrically coupled to an RF trace.

16. The apparatus of claim 11, wherein the pullup transistor and the pulldown transistor are configured to be in different states during operation of the apparatus.

17. An apparatus, comprising:
a board;
an electrically conductive trace on the board;
a plurality of switched shunt capacitors that are each electrically coupled to the board, wherein each of the plurality of switched shunt capacitors are configured to be charged and discharged by a corresponding circuit that comprises a transistor with a semiconductor material with a bandgap that is 1.5 eV or higher.

18. The apparatus of claim 17, wherein the plurality of switched shunt capacitors comprises a plurality of different capacitance values.

19. The apparatus of claim 17, wherein each of the plurality of switched shunt capacitors are controlled by a pair of transistors arranged in a half-bridge configuration.

20. The apparatus of claim 17, wherein each of the plurality of switched shunt capacitors comprises a switch along an electrical path between a power source and a capacitor.
